(19) United States
(12) Patent Application Publication
(10) Pub. No.: US 2009/0186457 A1
(43) Pub. Date: Jul. 23, 2009

(54) ANNEAL SEQUENCE INTEGRATION FOR CMOS DEVICES

(75) Inventors: Kam-Leung Lee, Putnum Valley, NY (US); Paul M. Kozlowski, Poughkeepsie, NY (US)

Correspondence Address: SCULLY, SCOTT, MURPHY & PRESSER, P.C., 400 GARDEN CITY PLAZA, SUITE 300, GARDEN CITY, NY, 11530, US

(73) Assignee: INTERNATIONAL BUSINESS MACHINES CORPORATION, Armonk, NY (US)

(21) Appl. No.: 12/018,427

(22) Filed: Jan. 23, 2008

(51) Int. Cl. H01L 21/8238

(52) U.S. Cl. 438/231; 257/E21.634

(57) ABSTRACT

The present invention relates to semiconductor devices, and more particularly to a method for forming a CMOS semiconductor device, the method including a first integration anneal sequence for each NFET and a second integration anneal sequence for each PFET of the semiconductor device. The method includes providing a structure having an nFET gate stack and a pFET gate stack patterned on a substrate. A first disposable spacer is formed adjacent the nFET gate stack and a second disposable spacer is formed adjacent the pFET gate stack. A first doped S/D region and a second doped S/D region are then formed in the substrate. The first and second disposable spacers are removed after the first and second doped S/D regions are formed. A first halo implant and a first S/D extension region are formed adjacent the nFET gate stack after the first and second disposable spacers are removed. The structure is annealed using a RTA process. A first final spacer adjacent the nFET gate stack and the second final spacer adjacent the pFET gate stack are then formed after a second halo implant and a second S/D extension region are formed adjacent the pFET. The structure is annealed using a laser anneal process to form an NFET and a PFET on the substrate.

### FIELD OF THE INVENTION

The present invention relates to semiconductor devices, and more particularly to a method for forming a complementary metal-oxide semiconductor (CMOS) device, the method comprising a first integration anneal sequence for each n-type field effect transistor (NFET) and a second integration anneal sequence for each p-type field effect transistor (PFET) of the semiconductor device.

### BACKGROUND OF THE INVENTION

As smaller transistors are manufactured, thinner gate dielectric materials are needed to enhance device performance. Ultra shallow source/drain (S/D) junctions are becoming more challenging to produce as junction depth is required to be less than 30 nm for sub-100 nm CMOS devices. Activating the polysilicon gate electrode without causing dopant diffusion is a major challenge for front end of line (FEOL) processing. Conventional processes for activating the polysilicon gate electrode include a rapid thermal annealing (RTA) process. A tight balance exists between enhanced dopant activation and aggregated dopant diffusion. An aggressive activation anneal may lead to high carrier concentration, but the dopant may be driven into the gate dielectric layer or even into the channel region.

The balance becomes more difficult to maintain as device makers try to overcome poly-depletion. Poly-depletion is a reduction of activated dopants within the inversion region of a polysilicon layer. Poly-depletion accounts for an increasing fraction of Tox-inv (carrier concentration/poly-depletion) as gate lengths and gate dielectric thicknesses become smaller. For substrate features within the size of 130 nm and 90 nm, conventional thermal processes such as RTA and spike laser annealing are the main dopant activation methods.

Spike laser annealing produces transient temperatures near the silicon melting point within a few milliseconds, which results in high dopant activation with little dopant diffusion. This is a particular benefit for a process such as boron activation, since boron diffuses much faster than phosphorous and arsenic.

There is a need in the art for a process that enables the fabrication of high performance CMOS devices with low resistant device junctions.

### SUMMARY OF THE INVENTION

The present invention relates to semiconductor devices, and more particularly to a method for forming a complementary metal-oxide semiconductor (CMOS) device, the method comprising a first integration anneal sequence for each n-type field effect transistor (NFET) and a second integration anneal sequence for each p-type field effect transistor (PFET) of the semiconductor device.

Specifically, and in broad terms, the method for forming a semiconductor structure on a substrate according to the present invention comprises:

providing a structure having an nFET gate stack and a pFET gate stack patterned on the substrate;

forming a first disposable spacer adjacent the nFET gate stack and a second disposable spacer adjacent the pFET gate stack;

forming a first doped source/drain (S/D) region and a second doped S/D region in the substrate;

removing the first and second disposable spacers after the first and second doped S/D regions are formed;

forming a first halo implant and a first S/D extension region adjacent the nFET gate stack after the first and second disposable spacers are removed;

annealing the structure using a rapid thermal anneal (RTA) process;

forming a second halo implant and a second S/D extension region adjacent the pFET gate stack after the RTA process;

forming a first final spacer adjacent the nFET gate stack and a second final spacer adjacent the pFET gate stack after the second halo implant and the second S/ID extension region are formed; and

annealing the structure using a laser anneal process to form a n-type field effect transistor (NFET) and a p-type field effect transistor (PFET) on the substrate.

In a related aspect, the RTA process comprises a spike RTA.

In a related aspect, the laser anneal process comprises a spike laser anneal.

In a related aspect, forming the first and second doped S/ID regions comprises performing a S/D ion implantation process at a first implantation energy.

In a related aspect, forming the first and second halo implants comprises performing an ion implantation process at a second implantation energy, wherein the second implantation energy is less than the first implantation energy.

In a related aspect, forming the first and second S/D extension regions comprises performing an ion implantation process at a third implantation energy, wherein the third implantation energy is less than the second implantation energy.

In a related aspect, the nFET gate stack and the pFET gate stack are formed by deposition, lithography and etching.

In a related aspect, the nFET gate stack and the pFET gate stack each comprise a gate conductor and a gate dielectric located beneath the gate conductor.

Another aspect of the present invention relates to a method for forming a PFET on a substrate, comprising:

patterning a pFET gate stack on the substrate;

forming a disposable spacer adjacent the pFET gate stack;

forming a doped source/drain (S/D) region adjacent the disposable spacer;

removing the disposable spacer after the doped S/D region is formed;

annealing the pFET gate stack and the doped S/D region using a rapid thermal anneal (RTA) process;

forming a halo implant and a S/D extension region adjacent the pFET gate stack after the pFET gate stack and the doped S/D region are annealed;

forming a final spacer adjacent the pFET gate stack after the halo implant and the S/D extension region are formed; and,

annealing the pFET gate stack, the doped S/D region, the halo implant and the S/D extension region using a spike laser anneal process to form the PEET on the substrate.

In a related aspect, the method further comprises:

patterning an nFET gate stack on the substrate;

forming a first disposable spacer adjacent the nFET gate stack;

forming a first doped source/drain (S/ID) region adjacent the first disposable spacer;

removing the first disposable spacer after the first doped S/D region is formed;

forming a first halo implant and a first S/D extension region adjacent the first gate stack after the first disposable spacer is removed;

annealing the first halo implant and the first S/D extension region using the RTA process, wherein the annealing is performed prior to the formation of the halo implant and the S/D extension region adjacent the pFET gate stack;

forming a first final spacer adjacent the first gate stack after the RTA process; and

annealing the nFET gate stack, the first doped S/D region, the first halo implant and the first S/D extension region using a spike laser anneal process to form an NFET on the substrate.

In a related aspect, the RTA process comprises a spike RTA.

In a related aspect, forming the doped and first doped S/D regions comprises performing a S/D ion implantation process at a first implantation energy.

In a related aspect, forming the halo and the first halo implants comprises performing an ion implantation process at a second implantation energy, wherein the second implantation energy is less than the first implantation energy.

In a related aspect, forming the S/D extension and the first SD extension regions comprises performing an ion implantation process at a third implantation energy, wherein the third implantation energy is less than the second implantation energy.

In a related aspect, the nFET gate stack and the pFET gate stack each comprise a gate conductor and a gate dielectric located beneath the gate conductor.

In a related aspect, the nFET gate stack and the pFET gate stack are formed by deposition, lithography and etching.

In another aspect according to the present invention, a method is provided for forming a CMOS structure, which comprises providing a structure having an nFET gate stack and a pFET gate stack patterned on the substrate. A first disposable spacer is formed adjacent the nFET gate stack and a second disposable spacer is formed adjacent the pFET gate stack. A first doped S/D region and a second doped S/D region are then formed. The first and second disposable spacers are removed after the first and second doped S/D regions are formed. A first halo implant and a first S/D extension region are formed adjacent the nFET gate stack after the first and second disposable spacers are removed. The structure, including the first halo implant and the first S/D extension region, is annealed using a RTA process. A first final spacer adjacent the nFET gate stack and a second final spacer adjacent the pFET gate stack are then formed after a second halo implant and a second S/D extension region are formed. The structure is annealed using a laser anneal process to form an NFET and a PFET on the substrate. The second halo implant and the second S/D extension region are annealed using the laser anneal process only.

In a related aspect, the RTA process comprises a spike RTA.

In a related aspect, the laser anneal process comprises a spike laser anneal.

In a related aspect, forming the first and second doped S/D regions comprises performing a S/D ion implantation process at a first implantation energy. Furthermore, forming the first and second halo implants comprises performing an ion implantation energy at a second implantation energy. Forming the first and second S/D extension regions comprises performing an ion implantation process at a third implantation energy. The second and third implantation energies are less than the first implantation energy.

In a related aspect, the nFET gate stack and the pFET gate stack are formed by deposition, lithography and etching.

The present invention relates to semiconductor devices, and more particularly to a method for forming a CMOS device, the method comprising a first integration anneal sequence for each NFET and a second integration anneal sequence for each PFET of the semiconductor device. The present invention improves semiconductor device performance by providing separate anneal sequences to lower the S/D extension region resistance of the NFETs and PFETs.

### BRIEF DESCRIPTION OF THE DRAWINGS

FIGS. 1-8 are pictorial representations (through cross sectional views) illustrating the basic processing steps employed for forming an NFET and a PFET of a semiconductor device according to the present invention.

FIGS. 9-13 are pictorial representations (through cross sectional views) illustrating the basic processing steps employed for forming a PFET of a semiconductor device according to the present invention.

### DETAILED DESCRIPTION OF THE INVENTION

The present invention, which provides a method for forming a CMOS device, will now be described in greater detail by referring to the drawings that accompany the present application. It is noted that the drawings of the present application are provided for illustrative purposes and are thus not drawn to scale. Moreover, like and corresponding elements shown in the drawings are referred to by like reference numerals.

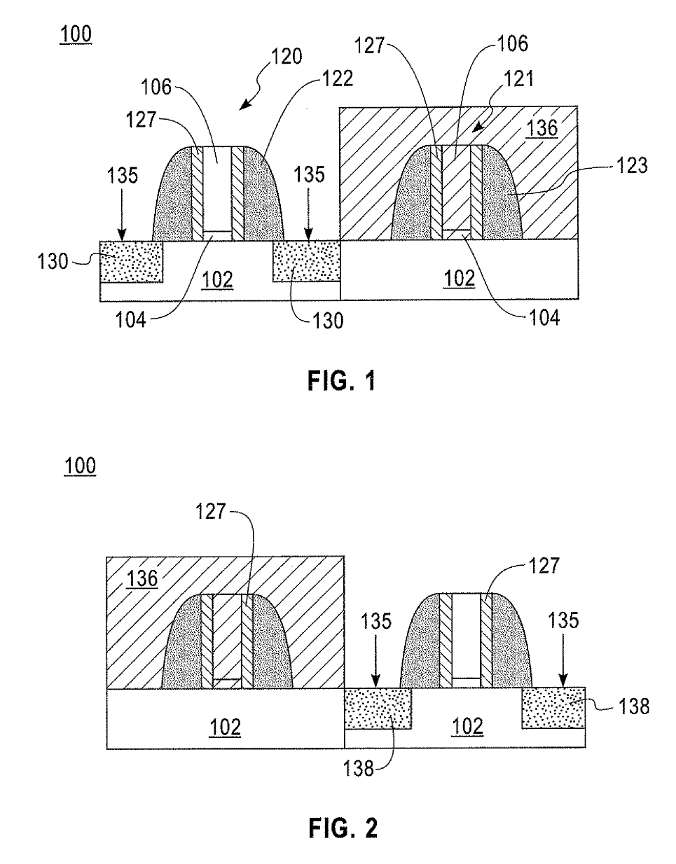

Reference is first made generally to FIGS. 1-8, which are cross sectional views of a structure 100 during various stages of an embodiment of the present invention. Although the drawings show the presence of a pair of gates (i.e., a CMOS transistor structure with PFET and NFET transistors), the present invention is not limited to that number of gates. Instead, the present integration process works for any number of gates. Hence, a plurality of gates may be present across a single semiconductor structure. Furthermore, it is noted that the semiconductor structure that can be formed in the present invention includes, for example, MOS capacitors, FETs, floating gate FET nonvolatile memory, dynamic random access memory (DRAM) and any other type of semiconductor device that includes a stack of a dielectric and a conductive material.

FIG. 1 shows an initial structure 100 that is employed in a method for forming a semiconductor structure 200, as shown in FIG. 8, on a substrate 102. Specifically, the initial structure 100 shown in FIG. 1 comprises an nFET gate stack 120 and a pFET gate stack 121 patterned on the substrate 102, wherein the nFET gate stack 120 and the pFET gate stack 121 are formed by deposition, lithography and etching. As shown, a first disposable spacer 122 is formed adjacent the nFET gate stack 120 and a second disposable spacer 123 is formed adjacent the pFET gate stack 121. The nFET gate stack 120 and the pFET gate stack 121 each comprise a gate conductor 106 and a gate dielectric 104 located beneath the gate conductor 106. This is the case if the dielectric is deposited as for a high-k material, but not if the dielectric is grown as is typical for SiO₂ or SiOₓN_{y}. In the present invention, conductive gate 106 and a gate silicide contact (not shown) are located atop selected portions of the gate dielectric 104 and the substrate 102.

The substrate 102 comprises any semiconducting material including, but not limited to: Si, Ge, SiGe, SiC, SiGeC, Ga, GaAs, InAs, InP and all other III/V compound semiconductors. The substrate 102 may also comprise a layered semiconductor such as Si/SiGe, a silicon-on-insulator (SOI) or a SiGe-on-insulator (SGOI). Preferably, the substrate 102 is a Si-containing substrate. The substrate 102 may be doped, undoped or contain doped and undoped regions therein. Although not shown, the substrate 102 includes a series of doped (n- or p-) well regions, as is well known in the art.

A process for forming the initial structure 100 shown in FIG. 1 will now be described. Although not shown, in a first step, isolation regions are formed into the substrate 102. Isolation regions may be trench isolation regions or field oxide isolation regions. Trench isolation regions are formed utilizing a conventional trench isolation process well known to those skilled in the art. For example, lithography, etching and filling of the trench with a trench dielectric may be used in forming the trench isolation regions. Optionally, a liner may be formed in the trench prior to trench fill. A densification step and a planarization process may be performed after the trench fill. The field oxide regions may be formed utilizing a so-called local oxidation of silicon process.

Next, well regions are formed by ion implantation and annealing. The type of dopant used in forming the wells is dependent on the final polarity of the FET. N-type dopants, such as an element from Group VA of the Periodic Table of Elements (e.g., As and P), are employed in forming the n-wells, while p-type dopants, such as an element from Group IIIA of the Periodic Table of Elements (e.g., B, In and Ga), are used in forming the p-wells. Notwithstanding the type of dopant used, each well region typically has a dopant concentration from about 1E17 to about 1E19 atoms/cm³, with a dopant concentration from about 1E17 to about 1E18 atoms/cm³ being more typical.

The implantation conditions used in forming each well region are conventional and are well known to those skilled in the art. For example, the implant conditions for forming an n-well region can include an n-type dopant dosage from about 1E12 to about 8E15 atoms/cm² and an energy from about 30 to about 1000 keV. The p-well region can be formed utilizing a p-type dopant dosage from about 1E12 to about 8E13 atoms/cm² and an energy from about 30 to about 600 keV. If a reach-through (n-type) implant is available in the technology, one would replace this implant for the standard n-well implants. Typically, this reach-through implant includes an n-type dopant such as Sb, wherein the dopant dosage is from 5E13 to 5E14 and an energy from 100 to 300 keV. The ion implantations can be performed using a substantially vertical ion implantation process, or alternatively, an angled ion implantation process.

An annealing process is used to activate the dopants within the well regions. A single annealing step can be used after the well region is formed, or alternatively, an anneal process can follow the implantation of each individual well region. The annealing temperature used in the present invention is typically from about 900° C. or greater, with an annealing temperature from about 100° C. or greater being more typical. The annealing times may vary depending on the type of anneal process used. For example, annealing times of about 5 minutes or less are typically used for a rapid thermal anneal (RTA) process, a laser annealing, or a spike anneal, while annealing times of about 30 minutes or greater are typically used for furnace annealing.

After forming the isolation regions and the well regions within the substrate 102, gate dielectric 104 is formed on the entire surface of the structure including the substrate 102 and atop the isolation regions if it is a deposited dielectric. The gate dielectric 104 can be formed by a thermal growing process such as, for example, oxidation, nitridation or oxynitridation. Alternatively, the gate dielectric 104 can be formed by a deposition process such as, for example, chemical vapor deposition (CVD), plasma-assisted CVD, atomic layer deposition (ALD), evaporation, reactive sputtering, chemical solution deposition and other like deposition processes. The gate dielectric 104 may also be formed utilizing any combination of the above processes.

The gate dielectric 104 is comprised of an insulating material including, but not limited to: an oxide, nitride, oxynitride and/or silicate. In one embodiment, it is preferred that the gate dielectric 104 is comprised of an oxide such as, for example, SiO₂, HfO₂, ZrO₂, Al₂O₃, TiO₂, La₂O₃, SrTiO₃, LaAlO₃, and mixtures thereof.

The physical thickness of the gate dielectric 104 may vary, but typically, the gate dielectric 104 has a thickness from about 0.5 to about 10 nm, with a thickness from about 0.5 to about 3 nm being more typical.

After forming the gate dielectric 104, a blanket gate electrode layer (i.e., polySi, SiGe, polySiGe, metal silicides, metals, etc.) is formed on the gate dielectric 104 utilizing a known deposition process such as, for example, physical vapor deposition, CVD or evaporation. Furthermore, advanced technologies (e.g., 32-nm node and beyond) may use a heterogeneous gate stack comprising a thin metal in contact with the gate dielectric, in this case high-k, and a polysilicon cap. The gate electrode layer may be doped or undoped. If doped, an in-situ doping deposition process may be employed in forming the same. Alternatively, a doped polySi layer can be formed by deposition, ion implantation and annealing. The doping of the polySi layer will shift the work function of the silicide gate formed. Illustrative examples of dopant ions include As, P, B, Sb, Bi, In, Al, Ga, TI or mixtures thereof, The thickness, i.e., height, of the gate electrode layer deposited at this point of the present invention may vary depending on the deposition process employed. Typically, the gate electrode layer has a vertical thickness from about 20 to about 180 nm, with a thickness from about 40 to about 150 nm being more typical.

Next, the gate electrode layer, and optionally a gate silicide contact layer (not shown) may be formed on the substrate 102 and then patterned by lithography and etching so as to provide the nFET gate stack 120 and the pFET gate stack 121. The lithography step includes applying a photoresist to the upper surface of the gate silicide contact layer, exposing the photoresist to a desired pattern of radiation and developing the exposed photoresist utilizing a conventional resist developer. The pattern in the photoresist is then transferred to the gate silicide contact layer and the gate conductor layer utilizing one or more dry etching steps. In some embodiments, the patterned photoresist may be removed after the pattern has been transferred into the gate silicide contact layer. In other embodiments, the patterned photoresist is removed after etching has been completed.

Suitable dry etching processes that can be used in the present invention for forming the nFET and pFET gates stacks 120, 121 include, but are not limited to: reactive ion etching, ion beam etching, plasma etching or laser ablation. The dry etching process employed is typically selective to the underlying gate dielectric 104 and therefore does not typically remove the gate dielectric. However, in some embodiments, this etching step may be used to remove portions of the gate dielectric 104 that are not protected by the NFET and pFET gates stacks 120, 121.

Next, as shown in FIG. 1, a first disposable spacer 122 is formed adjacent the RET gate stack 120 and a second disposable spacer 123 is formed adjacent the pFET gate stack 121. The first and second disposable spacers 122, 123 are comprised of an insulator such as an oxide, nitride, oxynitride and/or any combination thereof, and are formed by deposition and etching. In this embodiment, an optional oxide offset spacer 127 is formed on the nFET gate stack 120 and the pFET gate stack 121 prior to the formation of the first and second disposable spacers 122, 123. Furthermore, although not shown, one embodiment of the invention includes multiple spacers on each side sidewall having different widths. In another embodiment, the multiple spacer scheme is replaced by a wide single spacer. The width of the spacers must be sufficiently wide so that the source/drain silicide contacts (to be subsequently formed) do not encroach underneath the edges of the gate stack. Typically, the source/drain silicides do not encroach underneath the edges of the gate stack when the spacers have a width, as measured at the bottom, from about 20 to about 80 nm. When multiple spacers are used, each spacer can be composed of different insulators. For example, one spacer may be comprised of SiO₂ while another spacer may be comprised of Si₃N₄.

After formation of the first and second disposable spacers 122, 123, a first doped S/D region 130 is formed in the substrate 102. Forming the first doped S/D) region 130 comprises performing a S/D ion implantation process at a first implantation energy (represented in FIG. 1 by arrows 135). The first implantation energy 135 is a medium-energy implant step that is relatively lower than the high implantation energy used to form the doped (n- or p-) well regions in the substrate 102. In this embodiment, Arsenic ions are selectively implanted through a patterned photoresist 136.

As shown in FIG. 2, following the formation of the first and second disposable spacers 122, 123, a second doped S/D region 138 is formed in the substrate 102. Forming the second doped S/D region 138 comprises performing the S/D ion implantation process at the first implantation energy 135. In this embodiment, Boron ions are selectively implanted through the patterned photoresist 136.

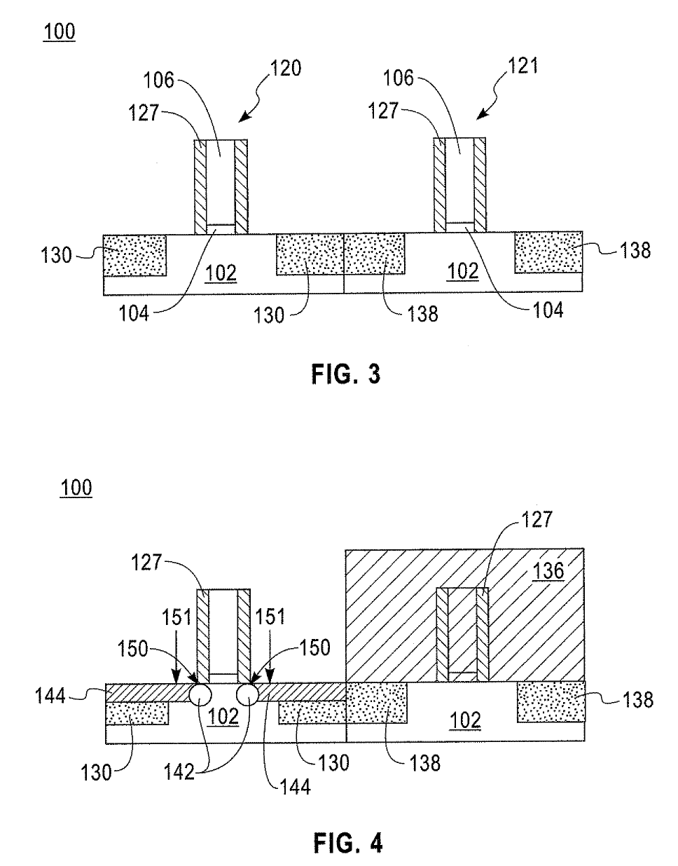

Next, as shown in FIG. 3, the first and second disposable spacers 122, 123 are removed following the formation of the first and second doped S/D regions 130, 138. In one embodiment of the invention, the first and second disposable spacers 122, 123 are removed using a reactive ion etching (RIE) process. In some cases, a wet chemical etch process can be used instead of the RIE process, or as a subsequent etch step following the RIE process. As is known in the art, the wet chemical etch process uses a chemical etchant such as acids, bases and solvents to chemically remove the disposable spacer material selective to the surface of the substrate 102.

In another embodiment of the invention, the removal method includes etching the first and second disposable spacers 122, 123 using a dry chemical etch process. As is known in the art, dry chemical etching uses a low-pressure plasma discharge to remove material on the substrate 102. The plasma creates reactive species that chemically react with the materials on the wafer surface. As with the other removal methods described herein, the dry chemical etch process removes the first and second disposable spacers 122, 123 selective to the surface of the substrate 102, as well as to the sidewalls of the NFET gate stack 120 and the pFET gate stack 121.

Next, as shown in FIG. 4, a first halo implant 142 and a first S/D extension region 144 adjacent the nFET gate stack 120 are formed after the first and second disposable spacers 122, 123 are removed. Forming the first halo implant 142 comprises performing a shallow ion implantation process at a second implantation energy (represented in FIG. 4 by arrows 150). The second implantation energy 150 is lower than in the previous implantation steps used to form the doped (n- or p-) well regions in the substrate 102 and the first and second doped S/D regions 130, 138. Forming the first S/D extension region 144 comprises performing a shallow ion implantation process at a third implantation energy (represented in FIG. 4 by arrows 151). The third implantation energy 151 is lower than the second implantation energy 150. In this embodiment, Arsenic ions are selectively implanted through the patterned photoresist 136.

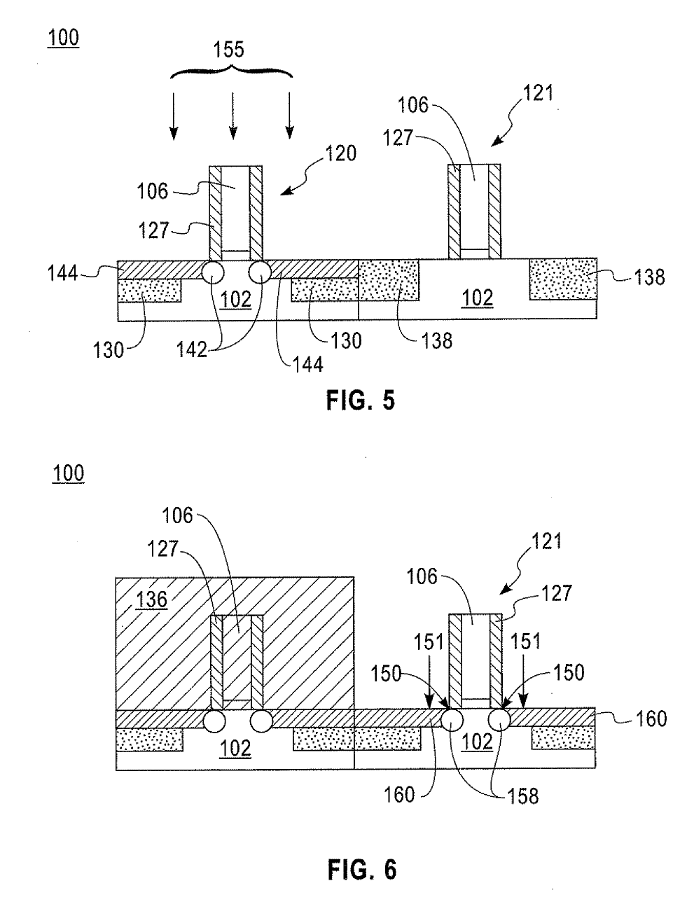

In a next step, as shown in FIG. 5, the entire structure, including nFET and pFET gate stacks 120, 121 the first and second doped S/D regions 130, 138, the first halo implant 142 and the first S/D extension region 144 are annealed using a rapid thermal anneal (RTA) process 155. The RTA process 155 uses a relatively fast ramp and short dwell time at a specific target temperature (i.e., approximately 1000° C.-1100° C.). A fast ramp rate and short dwell time is optimized to anneal the wafer to restore lattice damage and electrically activate the dopants while minimizing dopant diffusion into the silicon. The RTA process 155 is optimized for the first halo implant 142 and the first S/D extension region 144 of the nFET. In one embodiment of the invention, the RTA process 155 comprises a spike RTA. The spike RTA is characterized by a very fast ramp-up rate, typically in the range of 150° C./sec to 250° C./sec. The heating is stopped at the maximum desired temperature and then cooled quickly.

In a next step, as shown in FIG. 6, a second halo implant 158 and a second S/D extension region 160 are formed adjacent the pFET gate stack 121 after the RTA process 155. Forming the second halo implant 158 comprises performing an ion implantation process at the second implantation energy 150, wherein the second implantation energy is less than the first implantation energy 135 (FIGS. 1 and 2). The second implantation energy 150 is relatively lower than in the previous implantation steps used to form the doped (n- or p-) well regions in the substrate 102 and the first and second doped S/D regions 130, 138. Forming the second S/D extension region 160 comprises performing an ion implantation process at the third implantation energy 151. In this embodiment, boron or boron difluoride ions are selectively implanted through the patterned photoresist 136.

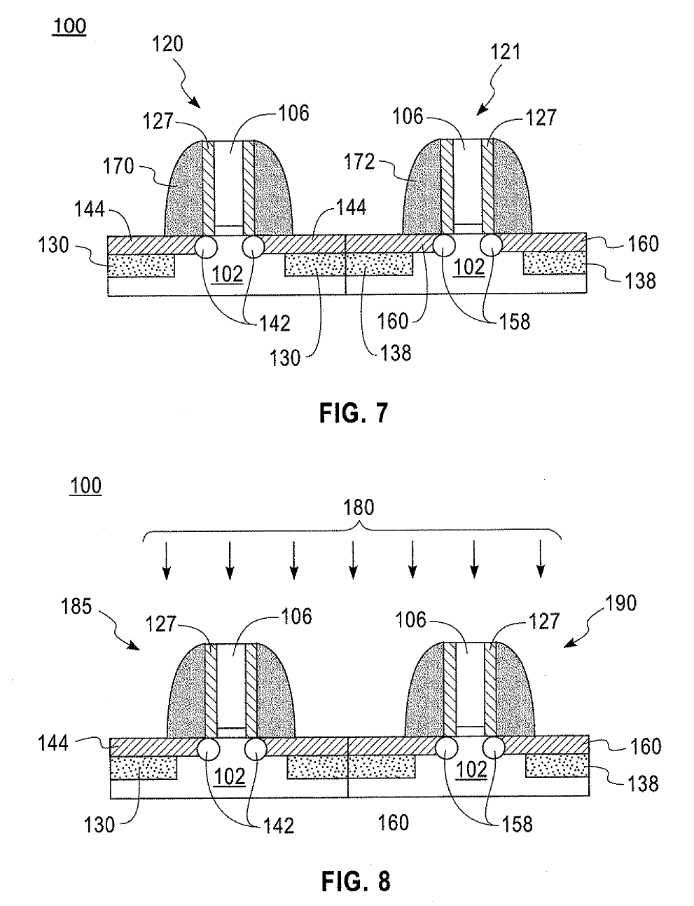

In a next step, as shown in FIG. 7, a first final spacer 170 is formed adjacent the nFET gate stack 120 and a second final spacer 172 is formed adjacent the pFET gate stack 121 following the formation of the second halo implant 158 and the second S/D extension region 160. The first and second final spacers 170, 172 comprise an insulator such as an oxide, nitride, oxynitride and/or any combination thereof, and are formed by deposition and etching. In one embodiment, the first and second final spacers 170, 172 are made using a low temperature (i.e., less than 400° C.) plasma enhanced chemical vapor deposition (PECVD) nitride spacer process to ensure minimal preamorphization implantation (PAI) regrowth of the PFET prior to the laser anneal process 180 (FIG. 8).

Next, as shown in FIG. 8, the entire structure 100 is annealed using the laser anneal process 180 to form an NFET 185 and a PFET 190 on the substrate 102. The NFET and pFET gate stacks 120, 121, the first and second halo implants 142, 158, as well as each of the first and second S/D extension regions 144, 160 are annealed using the laser anneal process 180. In a preferred embodiment, the laser anneal process 180 is a spike laser anneal (SLA). SLA scans a long, narrow beam from a laser across the structure 100 to create small, localized heating areas with a millisecond or shorter dwell time. SLA temperatures typically range from 1200° C. to 1350° C. Since only a thin layer at the top surface is heated and the bulk of the structure remains cool, the surface temperature falls quickly. The high peak temperature produces high dopant activation, while the short dwell time leads to minimal dopant diffusion. The processed region can be localized to specific areas on the structure 100 without affecting surrounding areas.

In the present invention, a lower sheet resistance (i.e., approximately 400 ohm/sq) is achieved for the PFET 190, including the ultra shallow boron junctions of the second S/D extension region 160, by using the laser anneal process 180 only. When compared to similar or smaller junctions (i.e., 30 nm or less), the sheet resistance of the second S/D extension region 160 is higher when the PFET 190 is formed with both the RTP process 155 and the laser anneal process 180. However, lower sheet resistance (i.e., approximately 250 ohm/sq) is achieved for the ultra shallow arsenic junctions of the first S/D extension region 144 when both the RTP process 155 and the laser anneal process 180 and are used to form the NFET. Accordingly, by providing separate anneal sequences, the present invention lowers poly-depletion and sheet resistance to optimize the S/D extension regions of the NFETs and PFETs, thus improving semiconductor device performance.

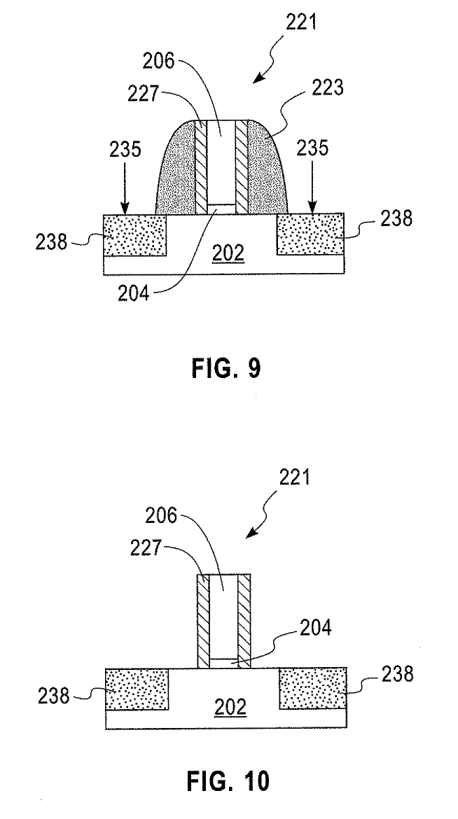

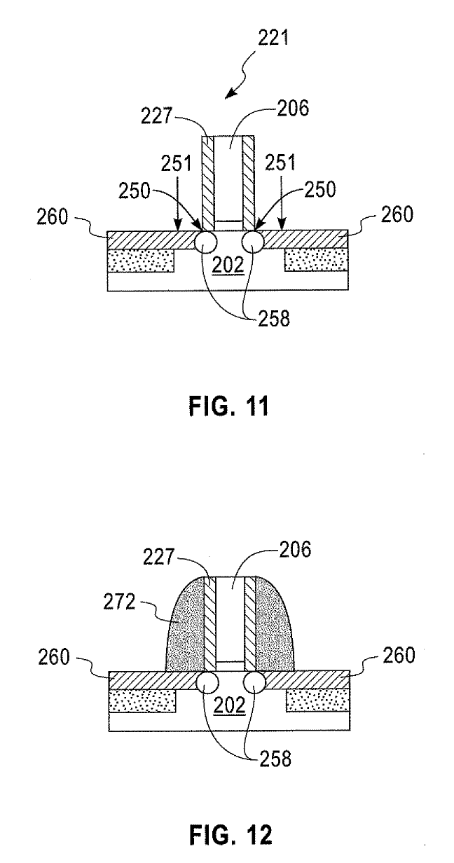

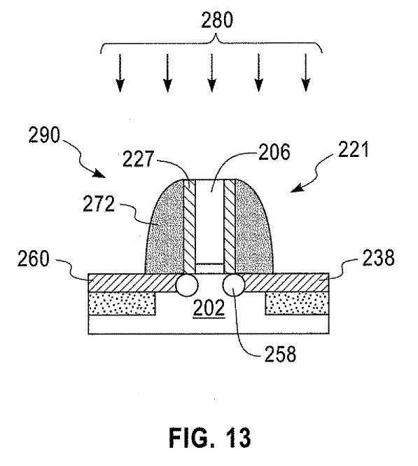

Another aspect of the present invention, as shown in FIGS. 9-13, relates to a method for forming a PFET on a substrate 202. As shown in FIG. 9, a pFET gate stack 221 is patterned on the substrate 202 and a disposable spacer 223 is formed adjacent the pFET gate stack 221 after the formation of an optional offset spacer 227. The pFET gate stack is formed by deposition, lithography and etching. The pFET gate stack 221 comprises a gate conductor 206 and a gate dielectric 204 located beneath the gate conductor 206. As also shown, a doped S/D region 238 is formed adjacent the disposable spacer 223 using a S/D ion implantation process at a first implantation energy 235. Next, as shown in FIG. 10, the disposable spacer 223 is removed after the doped S/D region 238 is formed. The pFET gate stack 221 and the doped S/D region 238 are then annealed using the RTA process. In FIG. 11, a halo implant 258 and a S/D extension region 260 are formed adjacent the pFET gate stack 221 after the pFET gate stack 221 and the doped S/D region 238 are annealed. Forming the halo implant 258 comprises performing an ion implantation process at a second implantation energy 250, wherein the second implantation energy 250 is less than the first implantation energy 235. Forming the S/f) extension region 260 comprises performing an ion implantation process at a third implantation energy 251. The third implantation energy 251 is less than the second implantation energy 250. Next, as shown in FIG. 12, a final spacer 272 is formed adjacent the pFET gate stack 221 after formation of the halo implant 258 and the S/D extension region 260. Finally, as shown in FIG. 13, the pEET gate stack 221, the doped S/D region 238, the halo implant 258 and the S/D extension region 260 are annealed using a spike laser anneal process 280 to form a PFET 290 on the substrate 202.

As similarly described above, although not shown in this embodiment, the method further comprises patterning an nFET gate stack on the substrate and forming a first disposable spacer adjacent the nFET gate stack. Next, a first doped S/D region is formed adjacent the first disposable spacer. The first disposable spacer is removed after the first doped S/D region is formed. A first halo implant and a first S/D extension region are then formed adjacent the NFET gate stack after the first disposable spacer is removed. Next, the first halo implant and the first S/D extension region are annealed using the RTA process, wherein the annealing is performed prior to the formation of the halo implant and the S/D extension region adjacent the pFET gate stack. A first final spacer is formed adjacent the nFET gate stack after the RTA process. Finally, the nFET gate stack, the first doped S/D region, the first halo implant and the first S/D extension region are annealed using a spike laser anneal process to form an NFET on the substrate.

Although not shown for the sake of brevity, a conventional CMOS fabrication process can be subsequently performed to complete the CMOS device, as is well known in the art.

While the present invention has been particularly shown and described with respect to preferred embodiments thereof, it will be understood by one skilled in the art that the foregoing and other changes in forms and details may be made without departing from the spirit and scope of the invention. It is therefore intended that the present invention is not limited to the exact forms and details described and illustrated, but falls within the spirit and scope of the appended claims.

1. A method for forming a semiconductor device on a substrate, comprising the steps of:
providing a structure having an nFET gate stack and a pFET gate stack patterned on the substrate;
forming a first disposable spacer adjacent the nFET gate stack and a second disposable spacer adjacent the pFET gate stack;
forming a first doped source/drain (S/D) region and a second doped S/D region in the substrate;
removing the first and second disposable spacers after the first and second doped S/D regions are formed;
forming a first halo implant and a first S/D extension region adjacent the nFET gate stack after the first and second disposable spacers are removed;
annealing the structure using a rapid thermal anneal (RTA) process;
forming a second halo implant and a second S/D extension region adjacent the pFET gate stack after the RTA process;
forming a first final spacer adjacent the nFET gate stack and a second final spacer adjacent the pFET gate stack after the second halo implant and the second S/D extension region are formed; and
annealing the structure using a laser anneal process to form a n-type field effect transistor (NFET) and a p-type field effect transistor (PFET) on the substrate.

2. The method of claim 1, wherein the RTA process comprises a spike RTA.

3. The method of claim 1, wherein the laser anneal process comprises a spike laser anneal.

4. The method of claim 1, wherein forming the first and second doped S/D regions comprises performing a S/D ion implantation process at a first implantation energy.

5. The method of claim 4, wherein forming the first and second halo implants comprises performing an ion implantation process at a second implantation energy, wherein the second implantation energy is less than the first implantation energy.

6. The method of claim 4, wherein forming the first and second S/D extension regions comprises performing an ion implantation process at a third implantation energy, wherein the third implantation energy is less than the second implantation energy.

7. The method of claim 1, wherein the nFET gate stack and the pFET gate stack each comprise a gate conductor and a gate dielectric located beneath the gate conductor.

8. A method for forming a p-type field effect transistor (PFET) on a substrate, comprising the steps of:
patterning a pFET gate stack on the substrate;
forming a disposable spacer adjacent the pFET gate stack;
forming a doped source/drain (S/D) region adjacent the disposable spacer;
removing the disposable spacer after the doped S/D region is formed;
annealing the pFET gate stack and the doped S/D region using a rapid thermal anneal (RTA) process;
forming a halo implant and a S/D extension region adjacent the pFET gate stack after the pFET gate stack and the doped S/D region are annealed;
forming a final spacer adjacent the pFET gate stack after the halo implant and the S/D extension region are formed, said forming the final spacer comprises depositing a nitride material utilizing plasma enhanced chemical vapor deposition performed at a temperature of less than 400° C.; and
annealing the pFET gate stack, the doped S/D region, the halo implant and the S/D extension region using a spike laser anneal process to form the PFET on the substrate.

9. The method of claim 8, further comprising:
patterning an nFET gate stack on the substrate;
forming a first disposable spacer adjacent the nFET gate stack;
forming a first doped source/drain (S/D) region adjacent the first disposable spacer;
removing the first disposable spacer after the first doped S/D region is formed;
forming a first halo implant and a first S/D) extension region adjacent the first gate stack after the first disposable spacer is removed;
annealing the first halo implant and the first S/D) extension region using the RTA process, wherein the annealing is performed prior to the formation of the halo implant and the S/D extension region adjacent the pFET gate stack;
forming a first final spacer adjacent the first gate stack after the RTA process; and
annealing the nFET gate stack, the first doped S/D region, the first halo implant and the first S/D) extension region using a spike laser anneal process to form an NFET on the substrate.

10. The method of claim 9, wherein the RTA process comprises a spike RTA.

11. The method of claim 9, wherein forming the doped and first doped S/D regions comprises performing a S/D) ion implantation process at a first implantation energy.

12. The method of claim 11, wherein forming the halo and the first halo implants comprises performing an ion implantation process at a second implantation energy, wherein the second implantation energy is less than the first implantation energy.

13. The method of claim 11, wherein forming the S/D extension and the first S/D) extension regions comprises performing an ion implantation process at a third implantation energy, wherein the third implantation energy is less than the second implantation energy.

14. The method of claim 9, wherein the nFET gate stack and the pFET gate stack are formed by deposition, lithography and etching.

15. A method for forming a complementary metal oxide semiconductor (CMOS) device on a substrate comprising;
providing a structure having an nFET gate stack and a pFET gate stack patterned on the substrate;
forming a first disposable spacer adjacent the nFET gate stack and a second disposable spacer adjacent the pFET gate stack;
forming a first doped source/drain (S/D) region and a second doped S/D region in the substrate;
removing the first and second disposable spacers after the first and second doped S/D regions are formed;
forming a first halo implant and a first S/D extension region adjacent the nFET gate stack after the first and second disposable spacers are removed;
annealing the structure using a rapid thermal anneal (RTA) process;
forming a second halo implant and a second S/D extension region adjacent the pFET gate stack after the RTA process;
forming a first final spacer adjacent the nFET gate stack and a second final spacer adjacent the pFET gate stack after the second halo implant and the second S/D extension region are formed; and
annealing the structure using a laser anneal process to form a n-type field effect transistor (NFET) and a p-type field effect transistor (PFET) on the substrate, wherein the second halo implant and the second S/D extension region are annealed using the laser anneal process only.

16. The method of claim 15, wherein the RTA process comprises a spike RTA.

17. The method of claim 15, wherein the laser anneal process comprises a spike laser anneal.

18. The method of claim 15, wherein forming the first and second doped S/D regions comprises performing a S/D ion implantation process at a first implantation energy.

19. The method of claim 18, wherein forming the first and second halo implants comprises performing an ion implantation process at a second implantation energy, wherein the second implantation energy is less than the first implantation energy.

20. The method of claim 18, wherein forming the first and second S/D extension regions comprises performing an ion implantation energy at a third implantation energy, wherein the third implantation energy is less than the second implantation energy.
